(19) United States
(12) Patent Application Publication
(10) Pub. No.: US 2008/0036032 A1
(43) Pub. Date: Feb. 14, 2008

(54) SEMICONDUCTOR DEVICE

(75) Inventor: Hideaki Nonami, Ome (JP)

Correspondence Address: MILES & STOCKBRIDGE PC, 1751 PINNACLE DRIVE, SUITE 500, MCLEAN, VA, 22102-3833, US

(73) Assignee: Hitachi, Ltd.

(21) Appl. No.: 11/768,740

(22) Filed: Jun. 26, 2007

(30) Foreign Application Priority Data
Aug. 10, 2006 (JP) 2006-217715

(51) Int. Cl. H01L 29/00

(52) U.S. Cl. 257/529; 257/E29.001

(57) ABSTRACT

A trimming element for trimming a redundant circuit and a high-accuracy resistance in consideration of the stability and the ease of fuse cutting, and more specifically a trimming element which is easily formed by an existing process. An SOI substrate, a heater connected to the SOI substrate, and a fuse connected to the heater are formed.

### CLAIM OF PRIORITY

The present application claims priority from Japanese application JP 2006-217715 field on Aug. 10, 2006, the content of which is hereby incorporated by reference into this application.

### FIELD OF THE INVENTION

The present invention relates to a semiconductor device and, specifically, relates to a structure of a trimming element supplied to trim a redundant circuit and a high-accuracy resistance, etc.

### BACKGROUND OF THE INVENTION

A fuse cutting method is well known as a trimming technique for a redundant circuit and a high-accuracy resistance, etc. A method is used as a fuse cutting method, in which a fuse part formed of a metallic lead line and polycrystalline silicon, etc. is fused by irradiating a laser beam thereto and cut by applying a current. The current application method is adopted as an efficient trimming technique because fuse cutting can be done by common use of an element measuring device. JP-A No. 2003-78013 is a document describing a trimming technique. Specifically, FIG. 2 shows an example of a trimming element, which includes resistances for heating and a fuse part, as a technology which makes it possible to melt the fuse and enables trimming with high reliability.

### SUMMARY OF THE INVENTION

The inventors have studied a trimming technique prior to this application. A trimming element where resistances for heating are arranged right underneath the fuse is shown in FIG. 2 of JP-A No. 2003-78013. However, this trimming method needs a step for forming a polycrystalline silicon film resistance element for a heater and variations in dimension may result because of, for instance, exposure conditions, etc. in the patterning process of the polycrystalline silicon film, so that there is a problem of the trimming yield becoming worse. Therefore, in the present invention, a trimming technique was discussed in which a polycrystalline silicon film is not used and another heat generation method is used.

An example of one typical of this invention is shown as follows. That is, a semiconductor device includes a Silicon-On-Insulator semiconductor substrate (SOI substrate), an isolation groove, a heater, and a fuse.

The feature of the present invention is (1) a semiconductor device including a semiconductor substrate, a plurality of heaters formed over the semiconductor substrate in which each or a plurality thereof are separated by isolation grooves, and a fuse formed over the plurality of heaters through an insulation film.

It is preferable that (2) the semiconductor substrate be an SOI substrate in (1). (3) The aforementioned heater may be a structure where a buried silicon oxide film of the SOI substrate is separated by an isolation groove in (2). Isolation of the heater can be more effectively performed by using the buried silicon oxide film of the SOI substrate. Isolation of the heater is effective as a result of the sidewall and the buried silicon oxide film.

In any of (1) to (3), it is preferable that (4) the aforementioned heating element be a bipolar transistor. By using the heating element of the semiconductor itself as a heater, isolation becomes possible even when it is a simple structure.

In any of (1) to (4), it is preferable that (5) the aforementioned heaters be arranged in parallel. In any of (1) to (5), a semiconductor device has the characteristics that (6) the heater and the fuse are energized. When the amount of self-heating is enough only using the heater, there is no necessity to energize the fuse.

A semiconductor device according to the present invention includes a trimming element including a heating element formed over an SOI substrate, etc., an isolation groove which separates the heating element, and a fuse part consisting of a conductor film which is formed over the heating element through an insulation film. In a semiconductor device of the present invention, the heater is surrounded by isolation grooves formed of a silicon oxide film with a small thermal conductivity and a buried silicon oxide film of the SOI substrate, and, moreover, the exothermic efficiency is improved by arranging the heaters in parallel.

Trimming a highly accurate resistance, etc. becomes possible by using an isolated heater and fuse, and the fuse can be cut stably and easily by heating the heater and energizing the fuse part. As a result, highly reliable trimming becomes possible.

### BRIEF DESCRIPTION OF THE DRAWINGS

FIG. 1 is a block diagram illustrating a trimming circuit of the present invention;

FIG. 2 is a plane structural diagram illustrating an example of a trimming element of FIG. 1;

FIG. 3 is a cross-sectional structural diagram at the line X-X;

FIG. 4 is a plane structural diagram illustrating another example of a trimming element of FIG. 1; and

FIG. 5 is a cross-sectional structural diagram at the line Y-Y.

### DETAILED DESCRIPTION OF THE PREFERRED EMBODIMENTS

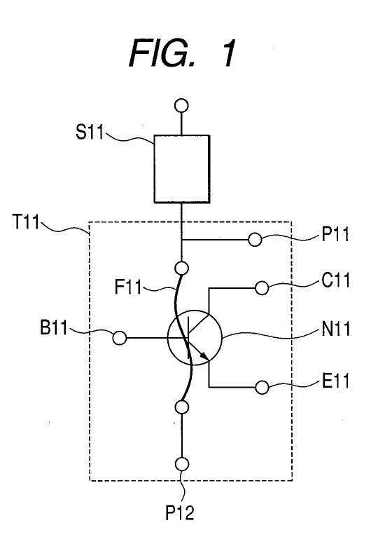

FIG. 1 is an embodiment of a semiconductor device of the present invention, a so-called trimming circuit. The trimming circuit is one where a trimming element T11 including a fuse part F11 and a bipolar transistor for heating N11 underneath the fuse is connected to the circuit being separated S11 in series. The fuse part and the heating element are electrically separated by an insulation film. The transistor for heating N11 is energized by applying a voltage to the input terminals B11, E11, and C11 thereof, and it is allowed to self-heat only when the fuse F11 is cut. At the same time, by energizing the input terminals P11 and P12 connected to both ends of the fuse part F11, the fuse F11 is cut. With respect of the current applied to the transistor and the heat output, it is necessary to obtain beforehand the current dependence of the heat output. It is possible that the circuit being separated S11 can be replaced with another element such as a resistive element, etc.

### First Embodiment

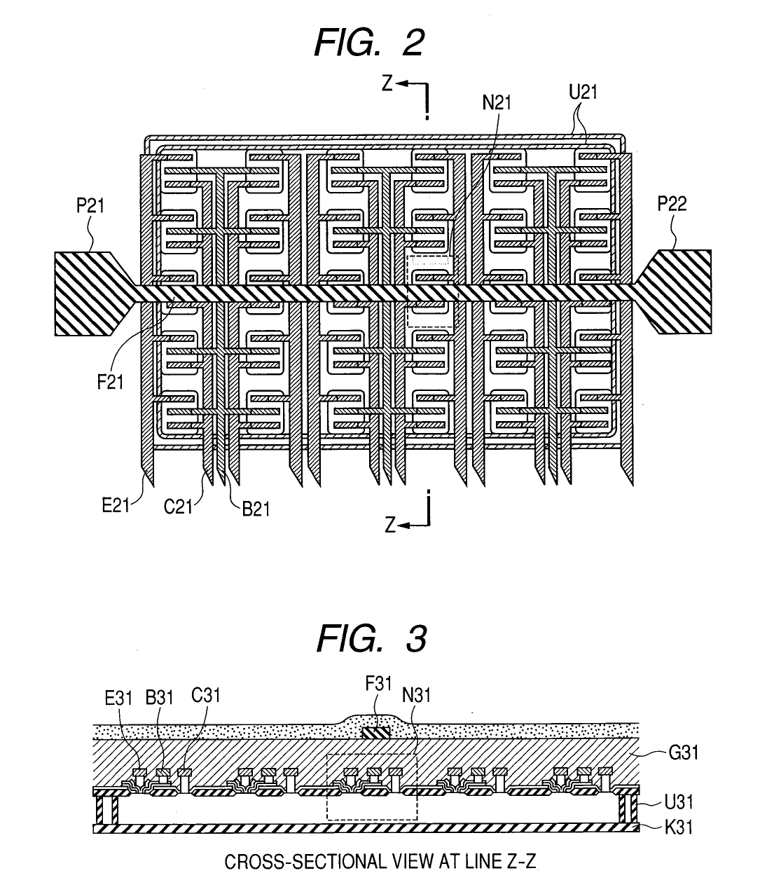

FIGS. 2 and 3 show one embodiment of a trimming element which is an example of a semiconductor device to which the present invention is applied. A plurality of bipolar transistors N21/N31 are formed in parallel as heating elements over the SOI substrate, and, surrounding it, single or multiple isolation grooves U21/U31 are formed of a silicon oxide film, etc. Moreover, a fuse part F21/F31 is formed of a metallic film such as Al, etc. over the bipolar transistors N21/N31 through an insulation film G31 composed of a silicon oxide film, etc. The bipolar transistors N21/N31 for heating are separated from the buried silicon oxide film K31 of the SOI substrate by the isolation grooves U21/U31. The bipolar transistors for heating formed in the isolation grooves are energized by applying a voltage to the electrodes B21/B31, E21/E31, and C21/C31 to heat up the bipolar element intentionally, and, at the same time, a current flows between the input terminals P21 and P22 of both ends of the fuse to execute the fuse cutting.

### Second Embodiment

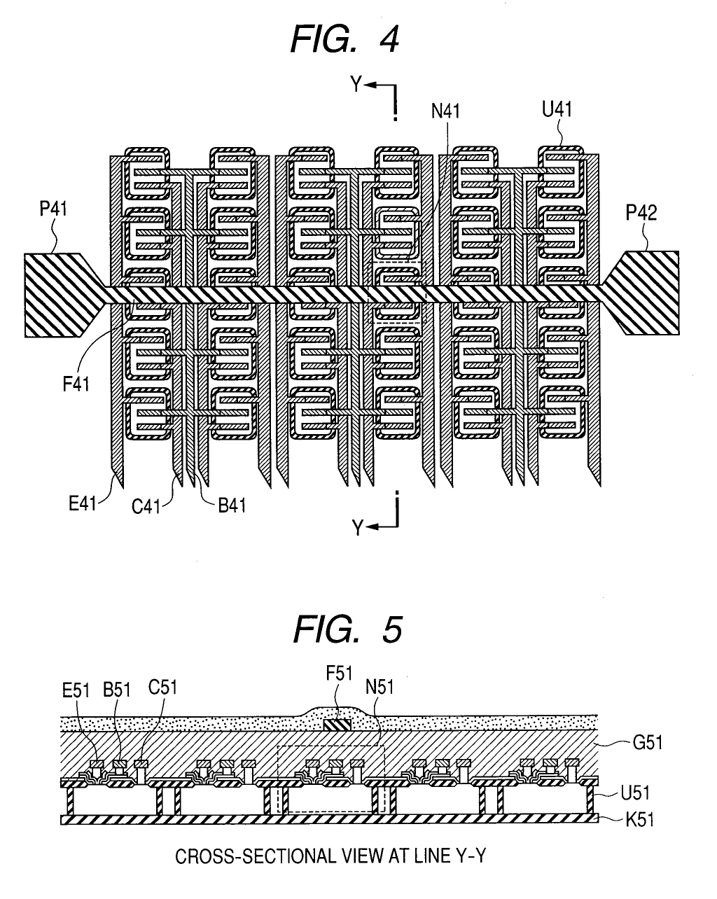

FIGS. 4 and 5 show another embodiment of a trimming element. A plurality of bipolar transistors N41/N51 are formed in parallel as heating elements over the SOI substrate, and an individual transistor is separated by the isolation grooves U41/U51. A fuse part F41/F51 is formed of a metallic film such as Al, etc. over the bipolar transistors N41/N51 through an insulation film G51 composed of a silicon oxide film, etc. the same as the first embodiment. Each bipolar transistor N41/N51 is separated from the buried silicon oxide film K51 of the SOI substrate by the individual isolation grooves U41/U51.

What is claimed is:

1. A semiconductor device comprising:
a semiconductor substrate;
a plurality of heaters formed over said semiconductor substrate in which each or a plurality thereof are separated by isolation grooves; and
a fuse formed over said plurality of heaters through an insulation film.

2. A semiconductor device according to claim 1,
wherein said semiconductor substrate is an SOI substrate.

3. A semiconductor device according to claim 2,
wherein said heaters are separated from a buried silicon oxide film in said SOI substrate by said isolation grooves.

4. A semiconductor device according to claim 1,
wherein said heaters are bipolar transistors.

5. A semiconductor device according to claim 1,
wherein said heaters are arranged in parallel.

6. A semiconductor device according to claim 1,
wherein said heaters and fuse are energized.
